(19) United States
(12) Patent Application Publication
(10) Pub. No.: US 2009/0051034 A1
(43) Pub. Date: Feb. 26, 2009

(54) Semiconductor device and method for the same

(75) Inventors: Chih-Yang Pai, Hsinchu (TW); Yuan-Hung Liu, Hsinchu (TW); Michael Kuang, Tao-Yuan County (TW); Kuo-Ching Huang, Hsinchu (TW)

Correspondence Address: REED SMITH LLP, Suite 1400, 3110 Fairview Park Drive, Falls Church, VA, 22042, US

(73) Assignee: Taiwan Semiconductor Manufacturing Co., Ltd.

(21) Appl. No.: 11/892,103

(22) Filed: Aug. 20, 2007

(51) Int. Cl. H01L 23/52; H01L 21/44

(52) U.S. Cl. 257/753; 438/644; 257/E21.476; 257/E23.141

(57) ABSTRACT

A method for forming a semiconductor device is provided. The method includes the following steps. A substrate having a first contact is provided. A layered structure is formed on the substrate. A recess is formed into the layered structure to expose at least a portion of the first contact. A glue layer is formed on the layered structure and the at least a portion of the first contact. The glue layer is removed from the at least a portion of the first contact. A second contact is formed contacting the first contact and the glue layer.

### TECHNICAL FIELD

The present invention relates to a semiconductor device and a method for the same, and more particularly to a semiconductor device with stacked contacts and a method for the same.

### BACKGROUND OF THE INVENTION

To have higher device density, elements of a semiconductor device may have non-planar structure, such as a trench capacitor or a stacked capacitor in a dynamic random access memory (DRAM) or an embedded DRAM. In this case, inter-level connections may be achieved by stacked contacts, since the aspect ratio of one single contact would be too high to realize.

However, the interface between stacked contacts is found to be critical to the RC time delay of semiconductor devices, especially for semiconductor devices with tight geometries. To raise the operation speed of semiconductor devices, the interface between stacked contacts should be improved.

### SUMMARY OF THE INVENTION

One object of the present invention is to improve the interface between stacked contacts, especially stacked contacts with glue layers.

One aspect of the present invention provides a method for forming a semiconductor device including the following steps. A substrate having a first contact is provided. A layered structure is formed on the substrate. A recess is formed into the layered structure to expose at least a portion of the first contact. A glue layer is formed on the layered structure and the at least a portion of the first contact. The glue layer is removed from the at least a portion of the first contact. A second contact is formed contacting the first contact and the glue layer.

The step of forming the second contact contacting the first contact and the glue layer mentioned above may include forming the second contact touching the at least a portion of the first contact and the glue layer. The step of forming a glue layer on the layered structure and the at least a portion of the first contact mentioned above may include forming the glue layer on the layered structure, a sidewall of the recess, and at least a portion of the first contact.

The step of removing the glue layer from the at least a portion of the first contact mentioned above may include etching the glue layer from the at least a portion of the first contact. The step of etching the glue layer from the at least a portion of the first contact mentioned above may include dry etching the glue layer from the at least a portion of the first contact. The step of etching the glue layer from the at least a portion of the first contact mentioned above may include sputter etching the glue layer from the at least a portion of the first contact.

The second contact mentioned above may include tungsten, aluminum, copper, or a combination thereof. The glue layer mentioned above may include titanium, titanium nitride, tantalum, tantalum nitride, tungsten nitride, ruthenium, or a combination thereof.

The semiconductor device formed by the method mentioned above may include a dynamic random access memory, and the method may further include the following steps. A portion of the second contact outside the recess is removed. A dielectric film is formed on the second contact and the glue layer. A metal structure is formed into the dielectric film. The metal structure may be a bit line.

The semiconductor device formed by the method mentioned above may include an embedded dynamic random access memory, and the method may further include the following steps. A portion of the second contact outside the recess is removed. A dielectric film is formed on the second contact and the glue layer. A bit line metal structure is formed into the dielectric film and electrically connecting the second contact. The substrate mentioned above may further include at least one logic device.

Another aspect of the present invention provides a semiconductor device. The semiconductor device includes a substrate having a first contact, a layered structure on the substrate, a recess formed into the layered structure to expose at least a portion of the first contact, a glue layer on the layered structure and a sidewall of the recess, and a second contact on the first contact within the recess and the glue layer, wherein the second contact contacts the first contact.

The second contact mentioned above may touch the at least a portion of the first contact. The second contact may include tungsten, aluminum, copper, or a combination thereof. The glue layer mentioned above may include titanium, titanium nitride, tantalum, tantalum nitride, tungsten nitride, ruthenium, or a combination thereof.

The semiconductor device mentioned above may be a dynamic random access memory, and may further include a dielectric film on the second contact and the glue layer, and a metal structure formed into the dielectric film. The metal structure may be a bit line.

The semiconductor device mentioned above may be an embedded dynamic random access memory, and may further include a dielectric film on the second contact and the glue layer, and a bit line metal structure formed into the dielectric film and electrically connecting said second contact. The substrate mentioned above may further include at least one logic device.

### BRIEF DESCRIPTION OF THE DRAWINGS

FIGS. 1A-1I illustrate an embodiment of a method for forming a semiconductor device according to the present invention and the semiconductor device thus formed; and

FIG. 2 illustrates how the present invention applies to a semiconductor device including another type of non-planar element.

### DETAILED DESCRIPTION OF THE PREFERRED EMBODIMENTS

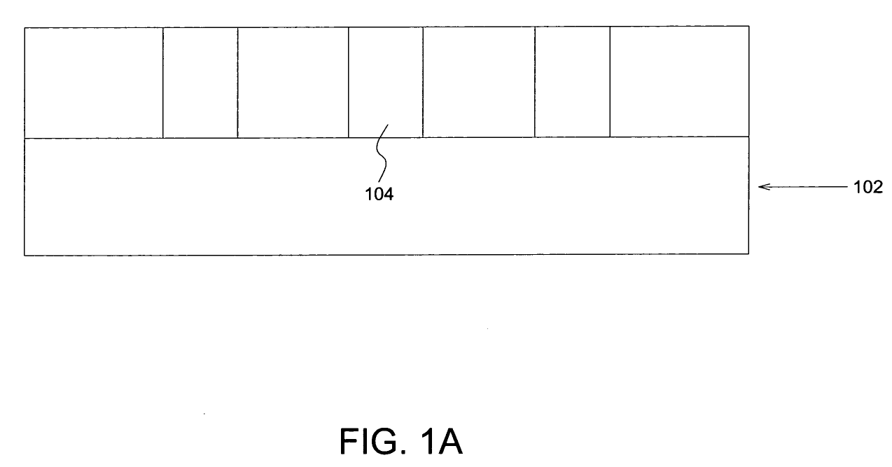

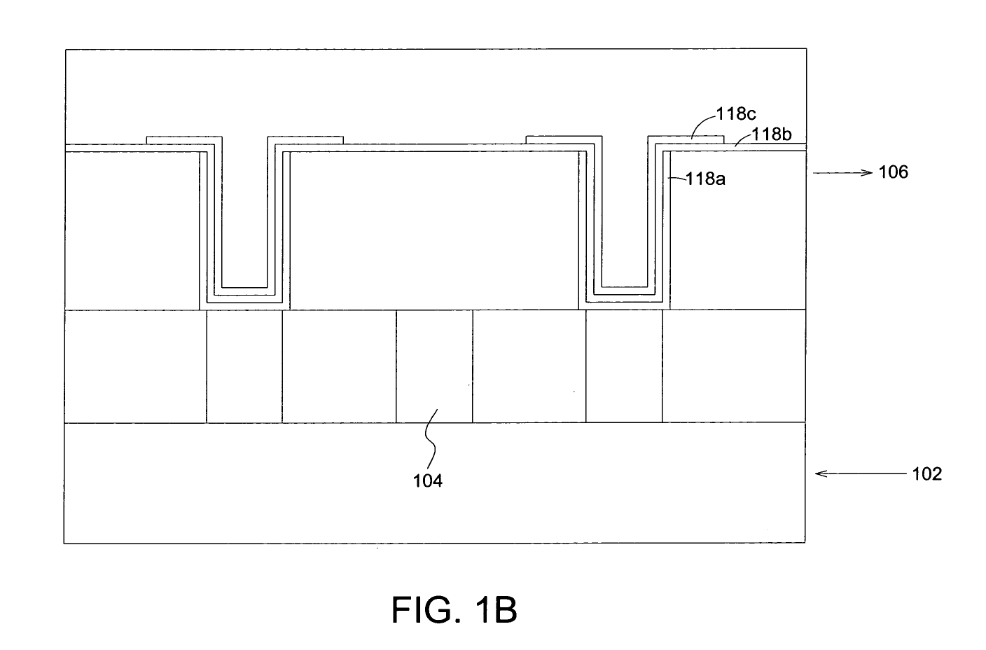

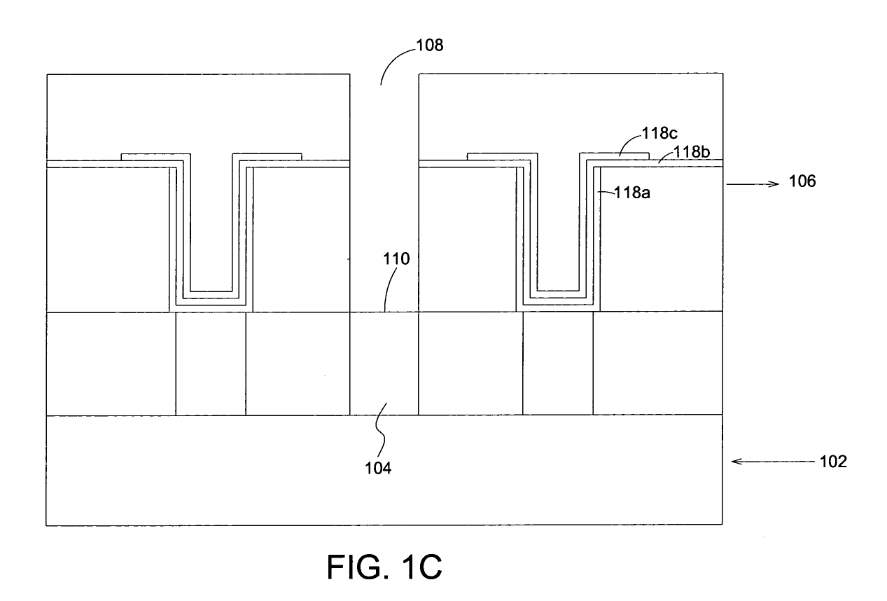

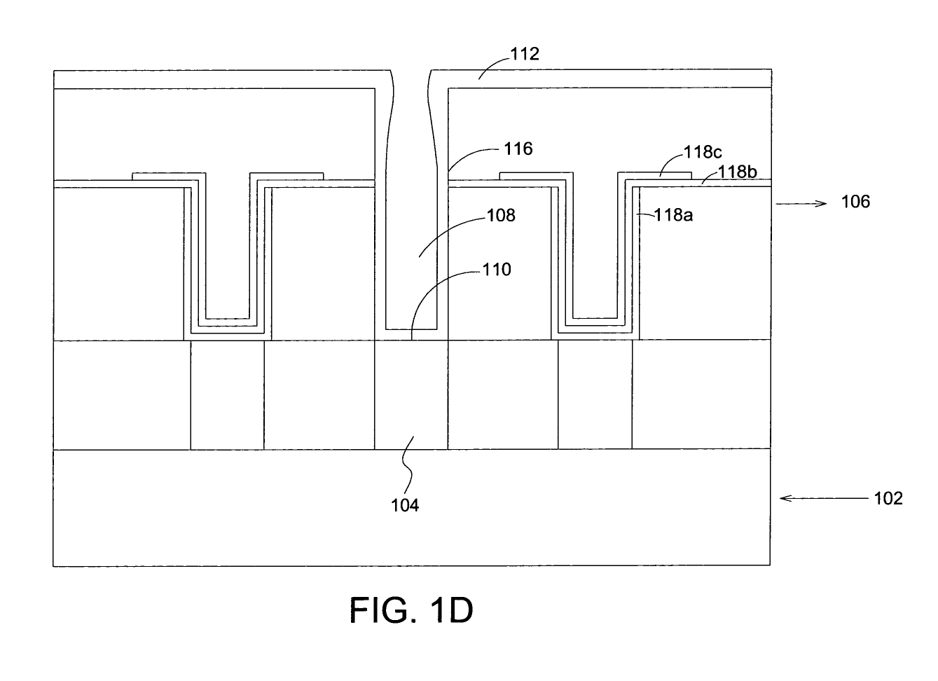

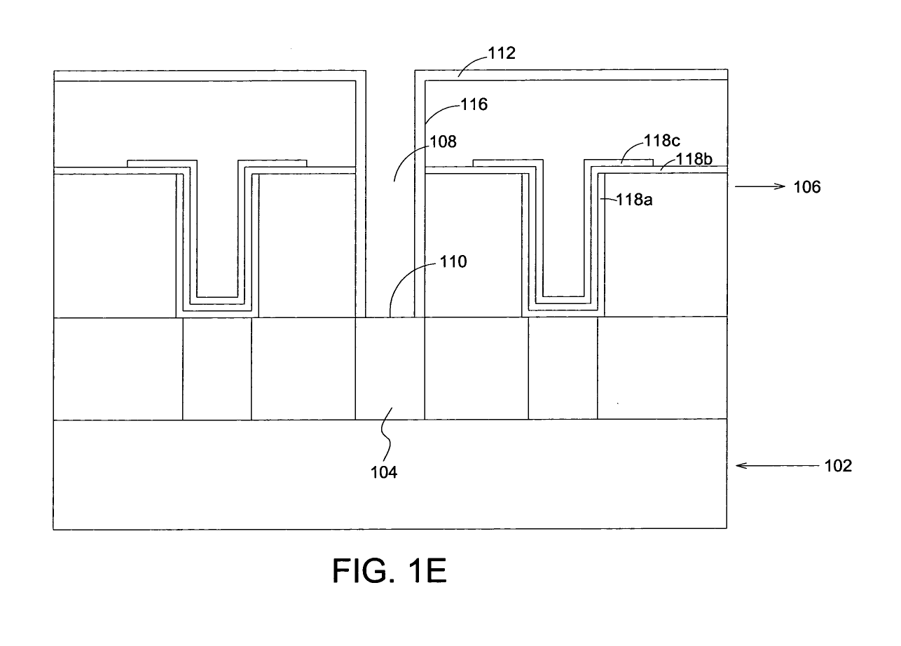

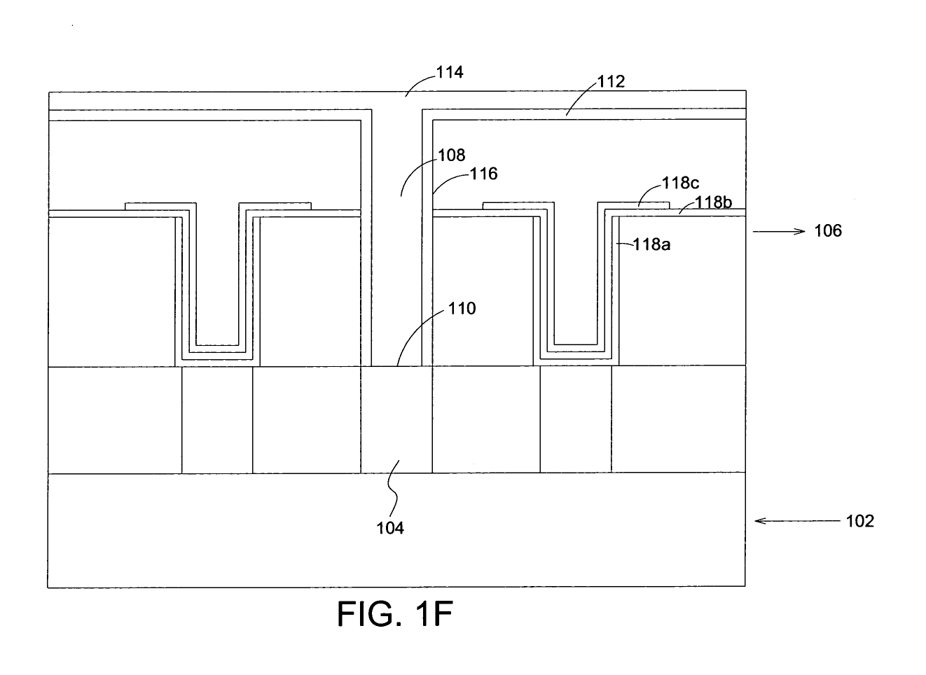

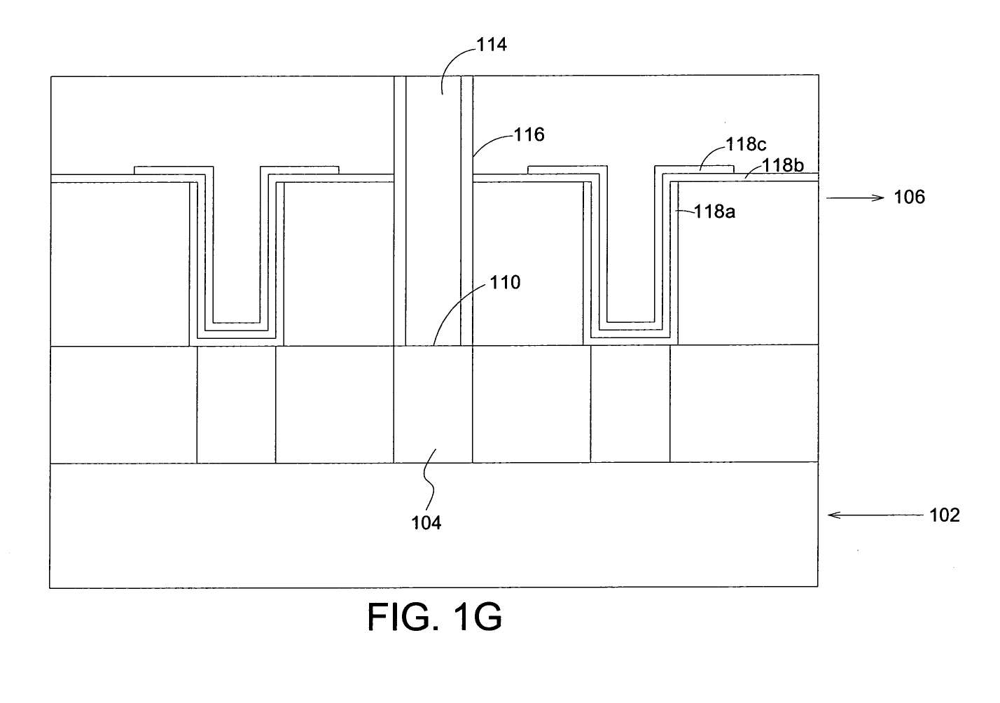

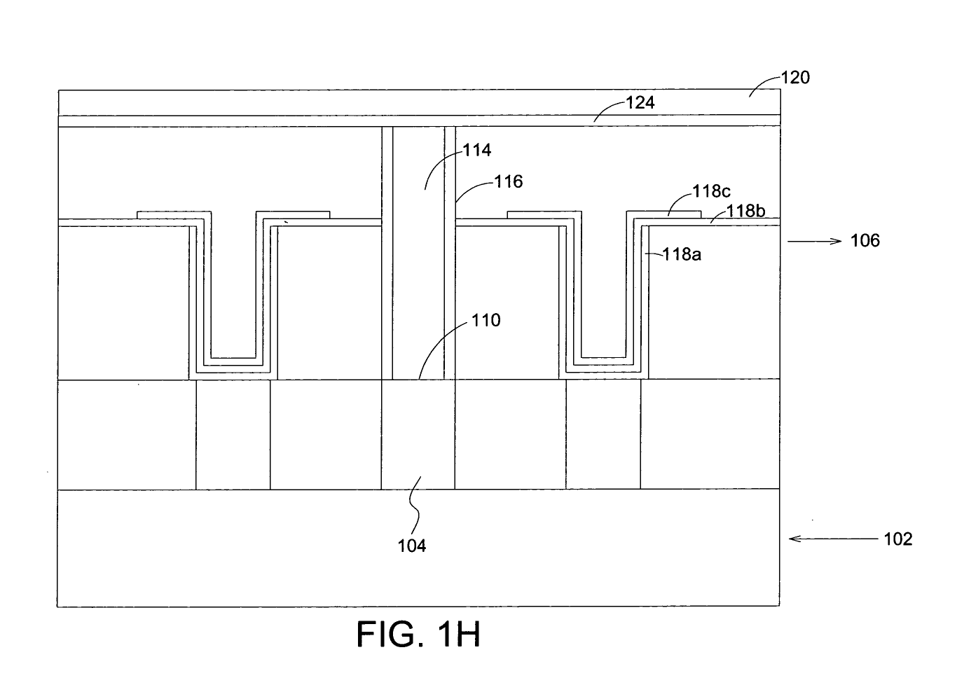

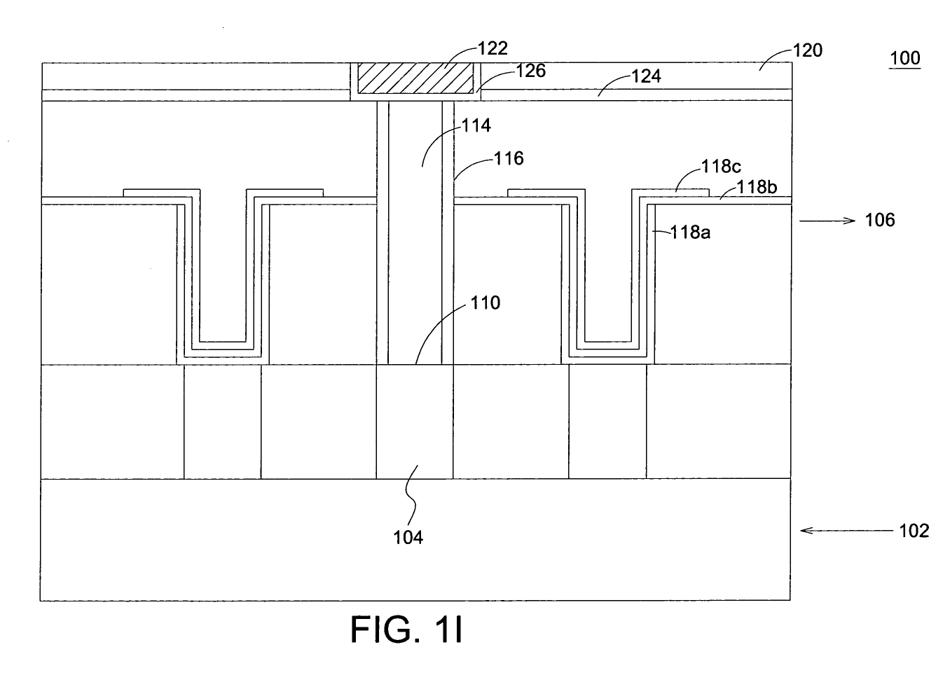

FIGS. 1A-1I are cross-sectional views illustrating an embodiment of a method for forming a semiconductor device according to the present invention and the semiconductor device 100 thus formed. The semiconductor device 100 may include a DRAM (dynamic random access memory) or an embedded DRAM.

Referring to FIG. 1A, a substrate 102 having a first contact 104 is provided. The substrate 102 may be a wafer under processing and may contain semiconductor devices, such as logic devices, to be coupled to structures thereabove via the first contact 104. The semiconductor devices contained in the substrate 102 may be consisted of poly-silicon, oxide, metals or any other conductive materials and dielectrics. The first contact 104 may include tungsten, aluminum, copper, or a combination thereof. The first contact 104 may be formed through the following steps. An etching process, such as wet etching, dry etching, or a combination thereof, is performed to form a hole into the substrate 102.

Then the hole is filled with the metal by, for example, the CVD (chemical vapor deposition) process, the sputtering process, the electroplating process, the electroless plating process, or a combination thereof. There may be a glue layer surrounding the first contact 104, which could be deposited by, for example, the CVD process, the sputtering process, or a combination thereof before the filling step. And the glue layer may include titanium, titanium nitride, tantalum, tantalum nitride, tungsten nitride, ruthenium, or a combination thereof.

Referring to FIG. 1B, a layered structure 106 is formed on the substrate 102. The layered structure 106 may include non-planar elements, such as traditional crown-shaped capacitors 118. The capacitors 118 may be formed on an oxide layer and include a bottom electrode 118a made of metal, an interelectrode dielectric layer 118b made of High-K materials, and a top electrode 118c made of metal. The bottom electrode 118a of the capacitor 118 may be formed through a deposition process followed by the CMP (chemical mechanical polishing) process. Referring to FIG. 1C, a recess 108 is formed into the layered structure 106 to expose at least a portion of a top surface 110 of the first contact 104. The recess 108 may be formed by the wet etching, the dry etching, or a combination thereof. Referring to FIG. 1D, a glue layer 112 is conformally formed on the layered structure 106, a sidewall 116 of the recess 108 and the top surface 110 of the first contact 104. The glue layer 112 may include titanium, titanium nitride, tantalum, tantalum nitride, tungsten nitride, ruthenium, or a combination thereof. The glue layer 112 could be deposited by, for example, the CVD process, the sputtering process, or a combination thereof.

Referring to FIG. 1E, the glue layer 112 is removed from the top surface 110 of the first contact 104. The glue layer 112 may be removed by etching or any other anisotropic methods, for example, dry etching or sputter etching. An exemplary condition for the glue layer 112 removal may be 3˜30mt/100˜500Ws/10˜100Wb/10˜100Cl₂/50˜500Ar. A portion of the glue layer 112 would remain on the layered structure 106 after the step of removing, for example, on a portion of the top surface of the layered structure 106.

Referring to FIG. 1F, a second contact 114 is formed contacting the first contact 104 and the glue layer 112. The glue layer 112 improves the adhesion of the second contact 114 to the layered structure 106 and thus facilitates the following process. However, the glue layer 112 at the interface between the second contact 114 and the first contact 104 would deteriorate the RC time delay of the final semiconductor device. For this reason, the glue layer 112 is removed from the top surface 110 of the first contact 104, as shown in FIG. 1E, therefore the second contact 114 touches the top surface 110 of the first contact 104 directly. Then the RC time delay of the final semiconductor device may be improved. The semiconductor device 100 according to the present invention is thus formed, as shown in FIG. 1F. The second contact 114 may include tungsten, aluminum, copper, or a combination thereof. The second contact 114 could be formed by, for example, the CVD process, the sputtering process, the electroplating process, the electroless plating process, or a combination thereof. Though the second contact 114 is shown to be formed on the entire glue layer 112 in this embodiment, it may be formed only on a portion of the glue layer 112 on demand.

FIGS. 1G-1I illustrate a possible subsequent process based on the embodiment shown in FIGS. 1A-1F. As shown in FIG. 1G, the portion of the second contact 114 outside the recess 108 and the portion of the glue layer 112 on the layered structure 106 are removed by, for example, the CMP (chemical mechanical polishing) process. Then referring to FIG. 1H, a metal structure stopper 124 including, say, silicon carbide may be formed on the second contact 114 and the layered structure 106. Then a dielectric film 120 made of oxide, nitride or other dielectrics may be formed on the metal structure stopper 124 by the oxidation process, the nitridation process, the deposition processes such as CVD or sputtering or the like. Next, as shown in FIG. 1I, a barrier layer 126 including, say, tantalum nitride and a metal structure 122, such as a bit line of a DRAM, for connection with components over the dielectric film 120 may be formed into the dielectric film 120. The metal structure 122 may include tungsten, aluminum, copper, or a combination thereof. The metal structure 122 may be formed by the common M1 process, including photolithography, etching and deposition processes.

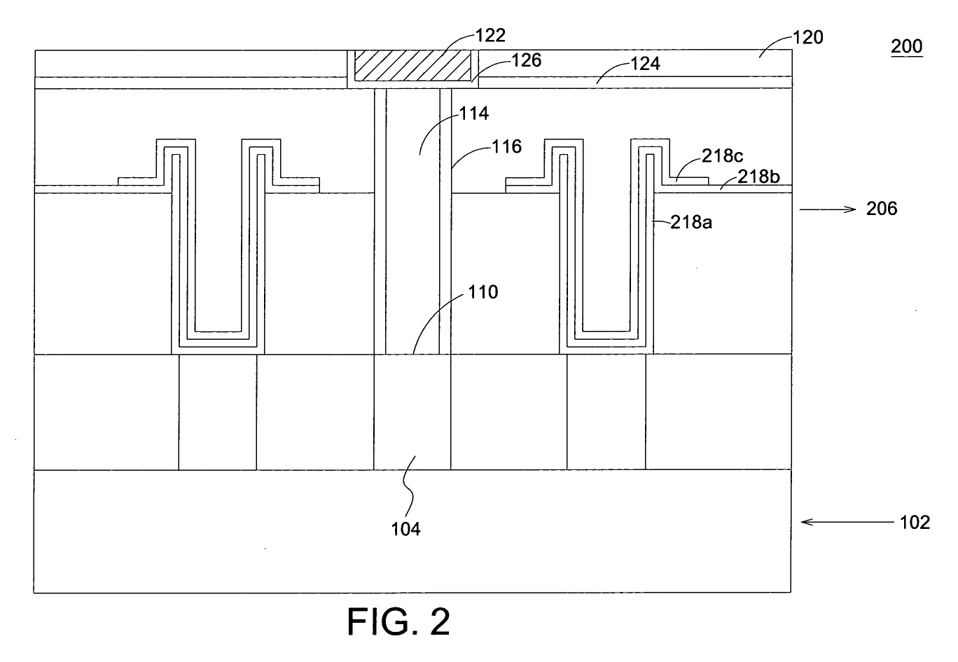

FIG. 2 illustrates how the present invention applies to a semiconductor device 200 including another type of non-planar element, such as recess crown-shaped capacitors 218. The recess crown-shaped capacitor 218 may include a bottom electrode 218a, an interelectrode dielectric layer 218b and a top electrode 218c. At least one of the bottom electrode 218a and the top electrode 218c may be made of polysilicon. The interelectrode dielectric layer 218b may be composed of any reliable insulator having a high dielectric constant, such as ONO (oxidized nitride on oxide), tantalum oxide or a combination thereof. The recess crown-shaped capacitor 218 may be formed by the following steps. A conductive layer, such as a polysilicon layer, may first be deposited by, for example, the CVD process. Then the photolithography and etching processes may be utilized to pattern the polysilicon layer into the bottom electrode 218a. Preferably, anisotropic etching such as RIE (reactive ion etching) may be used. The interelectrode dielectric layer 218b may be formed on the bottom electrode 218a by the oxidation process, the nitridation process, the deposition processes such as CVD or sputtering or the like. Next, another conductive layer, such as a polysilicon layer, may be deposited on the interelectrode dielectric layer 218b by, for example, the CVD process to form the top electrode 218c. Therefore, the recess crown-shaped capacitors 218 are formed. In this embodiment, the glue layer 112 is removed from the top surface 110 of the first contact 104. The glue layer 112 may be removed by etching or any other anisotropic methods, for example, dry etching or sputter etching. A portion of the glue layer 112 would remain on the layered structure 206 after the step of removing, for example, on a portion of the top surface of the layered structure 206. Therefore, the interface between the second contact 114 and the first contact 104 is improved, and the RC time delay of the final semiconductor device is alleviated.

Although only two stacked contacts are illustrated in the embodiments described above, the present invention applies to a larger number of stacked contacts as well.

The above description is only for preferred embodiments, but not to limit the scope of the present invention. Any other equivalent changes or modifications performed with the spirit disclosed by the present invention should be included in the appended claims.

We claim:

1. A method for forming a semiconductor device, comprising:
providing a substrate having a first contact;
forming a layered structure on said substrate;
forming a recess into said layered structure to expose at least a portion of said first contact;
forming a glue layer on said layered structure and said at least a portion of said first contact;
removing said glue layer from said at least a portion of said first contact; and
forming a second contact contacting said first contact and said glue layer.

2. The method according to claim 1, wherein said step of forming said second contact contacting said first contact and said glue layer comprises:
forming said second contact touching said at least a portion of said first contact and said glue layer.

3. The method according to claim 1, wherein said step of forming a glue layer on said layered structure and said at least a portion of said first contact comprises:
conformally forming said glue layer on said layered structure, a sidewall of said recess, and said at least a portion of said first contact.

4. The method according to claim 3, wherein said step of removing said glue layer from said at least a portion of said first contact comprises:
etching said glue layer from said at least a portion of said first contact.

5. The method according to claim 4, wherein said step of etching said glue layer from said at least a portion of said first contact comprises:
dry etching said glue layer from said at least a portion of said first contact.

6. The method according to claim 4, wherein said step of etching said glue layer from said at least a portion of said first contact comprises:
sputter etching said glue layer from said at least a portion of said first contact.

7. The method according to claim 1, wherein said second contact comprises tungsten, aluminum, copper, or a combination thereof.

8. The method according to claim 1, wherein said glue layer comprises titanium, titanium nitride, tantalum, tantalum nitride, tungsten nitride, ruthenium, or a combination thereof.

9. The method according to claim 1, wherein said semiconductor device comprises a dynamic random access memory, and said method further comprises:
removing a portion of said second contact outside said recess;
forming a dielectric film on said second contact and said glue layer; and
forming a metal structure into said dielectric film.

10. The method according to claim 9, wherein said metal structure is a bit line.

11. The method according to claim 1, wherein said semiconductor device comprises an embedded dynamic random access memory, and said method further comprises:
removing a portion of said second contact outside said recess;
forming a dielectric film on said second contact and said glue layer; and
forming a bit line metal structure into said dielectric film and electrically connecting said second contact.

12. The method according to claim 11, wherein said substrate further comprises at least one logic device.

13. A semiconductor device, comprising:
a substrate having a first contact;
a layered structure on said substrate;
a recess formed into said layered structure to expose at least a portion of said first contact;
a glue layer on said layered structure and a sidewall of said recess; and
a second contact on said first contact within said recess and said glue layer, wherein said second contact contacts said first contact.

14. The semiconductor device according to claim 13, wherein said second contact touches said at least a portion of said first contact.

15. The semiconductor device according to claim 13, wherein said second contact comprises tungsten, aluminum, copper, or a combination thereof.

16. The semiconductor device according to claim 13, wherein said glue layer comprises titanium, titanium nitride, tantalum, tantalum nitride, tungsten nitride, ruthenium, or a combination thereof.

17. The semiconductor device according to claim 13, wherein said semiconductor device is a dynamic random access memory, and said semiconductor device further comprises:
a dielectric film on said second contact and said glue layer; and
a bit line metal structure formed into said dielectric film and electrically connecting the second contact.

18. The semiconductor device according to claim 17, wherein said substrate further comprises at least one logic device.

19. The semiconductor device according to claim 13, wherein said semiconductor device is an embedded dynamic random access memory, and said semiconductor device further comprises:
a dielectric film on said second contact and said glue layer; and
a metal structure formed into said dielectric film.

20. The semiconductor device according to claim 19, wherein said metal structure is a bit line.
